(19) United States
(12) Patent Application Publication
(10) Pub. No.: US 2009/0121286 A1
(43) Pub. Date: May 14, 2009

(54) Integrated Circuit Comprising a Field Effect Transistor and Method of Fabricating the Same

(75) Inventors: Matthias Goldbach, Dresden (DE); Jurgen Faul, Radebeul (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/940,034

(22) Filed: Nov. 14, 2007

(51) Int. Cl. H01L 29/78; H01L 21/336

(52) U.S. Cl. 257/344; 438/306; 257/E29.269; 257/E21.435

(57) ABSTRACT

An integrated circuit includes a field effect transistor including: a gate electrode disposed adjacent to a surface of semiconductor substrate and a source/drain region disposed in the semiconductor substrate and adjacent to the surface. A net dopant concentration of a first section of the source/drain region decreases towards the gate electrode along a direction perpendicular to the surface.

### BACKGROUND

When scaling down field effect transistors, the off-state leakage current becomes a device characteristic of increasing importance with regard to low-power and stand-by applications. In the transistor off-state, a leakage current may flow between a network node electrically coupled to one of the source/drain regions of the field effect transistor and the semiconductor bulk, above which the field effect transistor is formed in a semiconductor substrate. One of the leakage mechanisms is the gate induced drain leakage (GIDL) current, which results from strong electrical fields being effective in the region of the pn-junctions between the source/drain regions and the channel region. A large drain-to-gate bias may bend the energy band for valence band electrons near the interface between the semiconductor substrate and the gate electrode, to such a degree that the valence-band electrons may tunnel into the conduction band.

A need exists therefore for an integrated circuit comprising field effect transistors with a low gate induced drain leakage current and a low resistance in the on-state.

### SUMMARY

Described herein are an integrated circuit and a method of fabricating the same. The integrated circuit includes a field effect transistor comprising: a gate electrode disposed adjacent to a surface of a semiconductor substrate and a source/drain region disposed in the semiconductor substrate and adjacent to the surface. A net dopant concentration of a first section of the source/drain region decreases towards the gate electrode along a direction perpendicular to the surface.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

Features and advantages of embodiments of the invention will be apparent from the following description of the drawings. The drawings are not necessarily to scale. Emphasis is placed upon illustrating the principles.

FIG. 1A is a schematic cross-sectional view of a planar n-MOSFET with a smooth net dopant concentration gradient at the substrate/gate dielectric interface according to an embodiment.

FIG. 1B is a graph depicting an example of a dopant profile of the embodied device of FIG. 1A.

FIG. 2 is a schematic cross-sectional view of a planar p-MOSFET with a smooth net dopant concentration gradient at the substrate/gate dielectric interface according to a further embodiment.

FIG. 3 is a schematic cross-sectional view of an asymmetric 3D-n-MOSFET with a smooth net dopant concentration gradient at the substrate/gate dielectric interface according to a further embodiment.

FIGS. 4A to 4B are cross-sectional views of a MOSFET during formation of the source/drain regions according to embodiments using a strictly confined deep implant and/or segregation.

FIGS. 5A to 5D are cross-sectional views of a MOSFET during the formation of the source/drain regions according to a further embodiment using a counter implant.

FIG. 6 is a flow-diagram illustrating a method of fabricating an integrated circuit in accordance with a further embodiment.

### DETAILED DESCRIPTION

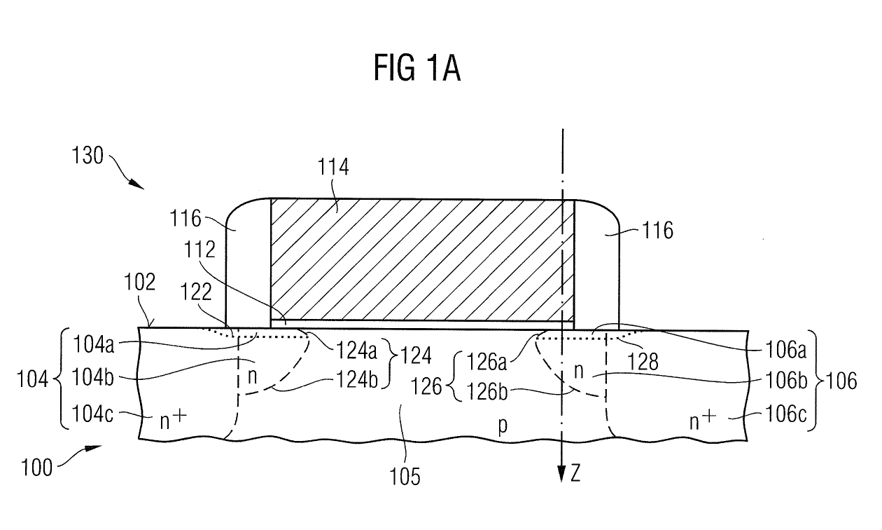

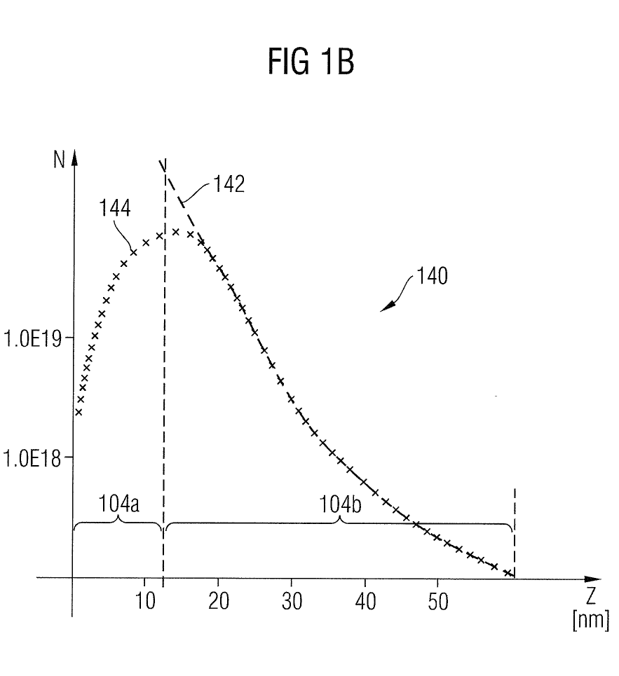

Referring to FIG. 1A, an n-MOSFET 130 comprises a gate electrode 114 bearing on a main surface 102 of a substrate 100. The MOSFET 130 may be, for example a “thick oxide” device configured to operate in a voltage range between about 3V and about 5V. The substrate 100 may be, for example, a preprocessed single crystalline silicon wafer or a silicon-on-insulator wafer and may comprise further doped and undoped sections, epitaxial semiconductor layers supported by a base conductor or a base insulator as well as other semiconductor and insulator structures that have previously been fabricated. A gate dielectric 112 separates the gate electrode 114 and the substrate 100.

The gate dielectric 112 may be a thermally grown silicon oxide layer. According to other embodiments, the gate dielectric 112 may be a deposited silicon oxide, for example, a silicon dioxide, which may be nitrided afterwards, or another oxide or silicon oxide of elements of the third or fourth group including oxides of rare earth, for example, Al₂O₃, HfO₂, HfSiO₂, CrSiO₂, DySiO₂ or another high-k material. The gate electrode 114 may comprise or consist of, for example, n-doped polysilicon or a metal or metal compound having a suitable work function. The gate electrode 114 may comprise a layer stack, for example, a polysilicon layer in contact with the gate dielectric 112, optionally a diffusion barrier layer bearing on the polysilicon layer and a metal layer, for example, a tungsten layer, bearing on the diffusion barrier layer. A p-doped channel region 105 may be formed within the substrate 100, faces directly the gate electrode 114 at the gate dielectric 112 and separates a first source/drain region 104 and a second source/drain region 106 which are formed within the substrate 100. The channel region 105 is of a first conductivity type. The first and the second source/drain regions 104, 106 are of a second conductivity type, which is the opposite of the first conductivity type. In accordance with the embodiment shown in FIG. 1A, the first conductivity type is the p-type and the second conductivity type is the n-type.

The gate electrode 114 is disposed above a surface, which, according to the illustrated embodiment, is the main surface 102 of the substrate 100. According to other embodiments, the surface may be the inner sidewall of a vertical or V-shaped groove formed in the substrate 100. The first and second source/drain regions 104, 106 are disposed within the substrate 100 and at least one of the first and second source/drain regions 104, 106, for example, the first one, adjoins the surface.

The net dopant concentration of, for example, the first source/drain region 104 decreases along a direction perpendicular to the surface towards the gate electrode 114. The net dopant concentration of the first source/drain region 104 may decrease towards the gate electrode 114 along a line that intersects the surface at that edge of the gate electrode 114 that is oriented to the first source/drain region 104. The reduced net dopant concentration may reduce the electrical field strength between the gate electrode 114 and the first source/drain region 104, wherein a gate induced drain leakage resulting from the electrical field may be reduced.

Both source/drain regions 104, 106 may overlap the gate electrode 114 such that a portion of each of the source/drain regions 104, 106 faces directly a portion of the gate electrode 114 at the gate dielectric 112. According to other embodiments, the first and second source/drain regions 104, 106 do not overlap with the gate electrode 114. The edges of the source/drain regions 104, 106 may also be approximately flush with the edges of the gate electrode 114. In accordance with further examples, the first source/drain region 104 and the second source/drain region 106 may be asymmetric with respect to the gate electrode 114. Each source/drain region 104, 106 may result from one, two, three or more implants, wherein each implant forms a corresponding doped portion within the substrate 100. The first source/drain region 104, for example, may result from a first implant forming an extension region 104b, which may be heavily or lightly doped, for example. The first implant may be, for example, approximately aligned to the edges of the gate electrode 114. The first source/drain region 104 may further comprise a heavily doped deep implant region 104c, which extends to a greater depth than the extension region 104b. The second implant may be aligned to the outer edges of gate spacers 116 extending along the vertical sidewalls of the gate electrode 114. According to other embodiments, using temporary or sacrificial spacers, the heavily doped deep implant regions 104c, 106c may be provided at various distances to the edges of the gate electrode 114. Low doped extension regions 104b, 106b may smooth the net dopant concentration gradient between the heavily doped deep implant regions 104c, 106c and the channel region 105. More heavily doped extension regions 104b, 106b may reduce the electrical resistance between the first and the second source/drain regions 104, 106 in the on-state of the MOSFET 130 and/or a contact resistance.

The source/drain regions 104, 106 and the channel region 105 adjoin to a main surface 102 of the semiconductor substrate 100. Between the channel region 105 and each of the source/drain regions 104, 106 an interface (pn-junction) 124, 126 is formed. Each pn-junction comprises a surface section 124a, 126a adjacent to the main surface 102, and a central section 124b, 126b adjacent to the surface section 124a, 126a.

A net dopant concentration gradient between the channel region 105 and, for example, the first source/drain region 104 in the surface section 124a is smoother than in the central section 124b of the interface 124. In the surface section 124a, an electrical field strength between the gate electrode 114 and the first source/drain region 104 is reduced.

A net dopant concentration of the first source/drain region 104 in a first section adjacent to the interface 124 and along a direction perpendicular to the main surface 102 has a peak in a first distance to the main surface 102 which is at least 5 m (e.g., 8 or 10 nm). In surface sections 104a, 106a of the source/drain regions 104, 106 and between the main surface 102 and the first distance, the net dopant concentration in the first section of the first source/drain region 104 increases with increasing distance to the main surface 102. Beyond the first distance, the net dopant concentration in the first section of the first source/drain region 104 decreases with increasing distance to the main surface 102. The first section may correspond, for example, approximately to the extension region 104b.

In accordance with an embodiment, the net dopant concentration gradient in a second section of the first source/drain region 104, which faces the channel region 105 at the first section may decrease with increasing distance to the main surface 102. The second section may correspond to the heavily doped deep implant region 104c. A first horizontal doping profile of the net dopant concentration parallel to the main surface 102 between the main surface 102 and the first distance may be smoother than a second horizontal doping profile parallel to the main surface 102 beyond the first distance. The second source/drain region 106 may have a similar or identical net dopant concentration gradient. According to other embodiments, the second source/drain region 106 is formed symmetrical to the first source/drain region 104.

The first distance of the net dopant concentration may decrease with increasing distance to the respective interface 124, 126 along a peak line 122, 128.

FIG. 1B shows a diagram 140 plotting the net dopant concentration gradient or doping profile along axis Z according to FIG. 1A. The axis runs through a first section of the second source/drain region 106, wherein the first section adjoins to the channel region 105. The net dopant concentration gradient 144 has a peak in a first distance of about 12 nm with reference to the main surface. Between the main surface at Z=0 and the first distance, the net dopant concentration increases with increasing distance to the main surface 102. Beyond the first distance, the net dopant concentration gradient 144 decreases with increasing distance to the main surface 102.

The doping profile as illustrated in the diagram 140 may result from an implant, the parameters of which, like dopant type, energy and/or dose are selected accordingly. For example, heavy ions with low diffusivity may be implanted with a medium implant depth corresponding to the first distance. According to another embodiment, the doping profile 144 may result from a shallow implant with a doping profile 142, wherein the dopants are selected to be capable of segregating into neighboring structures, for example the gate dielectric 112 or the gate spacer 116. By diffusing out into the gate dielectric 112, the gate spacer 116 or another neighboring structure, which may be a sacrificial structure of, for example, an oxide, the segregating ions convert the doping profile 142 into the doping profile 144.

According to yet another embodiment, a shallow counter doping, for example a counter implant, may partly neutralize the dopants in a surface section of a preceding implant with the doping profile 144.

Shifting the cross-section Z towards the channel region 105, the net dopant concentration gradient 144 becomes shallower, wherein the first distance may remain at the same first distance. Shifting the cross-section Z away from the channel region 105, the dopant profile 144 may become steeper, wherein the first distance may remain approximately the same in the area of the first section. In the area of the heavily doped deep implant region 106c, the first distance becomes smaller, while the dopant profile 144 becomes wide and high. In accordance with another embodiment, the peak dopant concentration along a cross-section within the area of the deep implant region 106c has a peak net dopant concentration at a first distance of less than 1 nm.

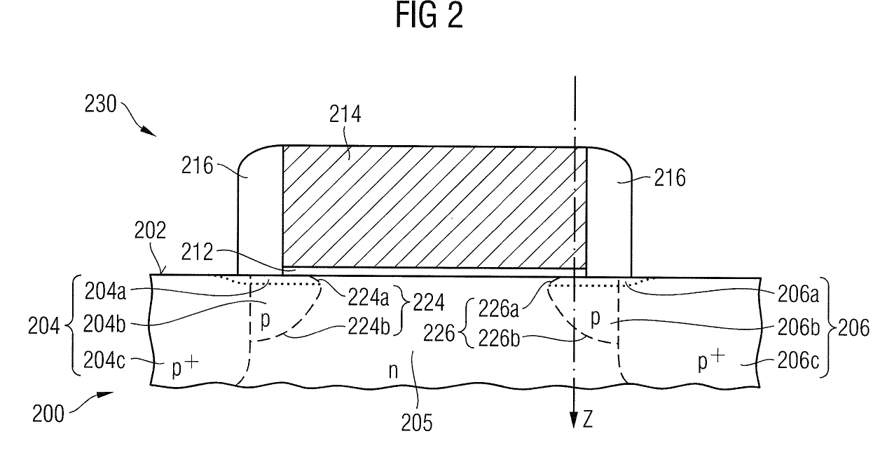

FIG. 2 refers to a p-MOSFET 230 with smooth net dopant concentration gradient near the main surface 202 of an n-doped semiconductor substrate 200. Within the semiconductor substrate 200, a first p-doped source/drain region 204 and a second p-doped source/drain region 206 are separated by an n-doped channel region 205. Each of the two source/drain regions 204, 206 may comprise a deep implant region 204c, 206c, which may be heavily doped, and an extension region 204b, 206b, which may be heavily or lightly doped. In accordance to other embodiments, each source/drain region 204, 206 may comprise one heavily doped region only or more doped regions. Further in accordance to other embodiments, the dopant concentration of the channel region 105 may be strengthened by heavily n-doped halo implants, which may, for example, result from tilted implants and that may smooth the net dopant concentration gradient between the channel region 205 and the respective source/drain region 204, 206 in a central section 224b, 226b of an interface 224, 226 between the channel region 205 and the respective source/drain region 204, 206. The first source/drain region 204 and/or the second source/drain 206 may further comprise a low doped surface section 204a, 206a in which the net dopant concentration increases with increasing distance to the main surface 202.

The first and second source/drain regions 204, 206 and the channel region 205 adjoin to the main surface 202 of the substrate 200. A gate dielectric 212 is in contact with the channel region 205 and may overlap with the first source/drain region 204 and/or the second source/drain region 206. The gate dielectric 212 separates a gate electrode 214 and the channel region 205. The gate electrode 214 may overlap with the first source/drain region 204 and/or the second source/drain region 206 such that a portion of the gate electrode 214 faces directly a portion of the first source/drain region 204 at the gate dielectric 212 and another portion of the gate electrode 214 faces directly a portion of the second source/drain region 206 at another portion of the gate dielectric 212. Gate spacers 216 may extend along the vertical sidewalls of the gate electrode 214. Between the first source/drain region 204 and the channel region 205 and between the second source/drain region 206 and the channel region 205 an interface 224, 226 is formed respectively. Each interface extends along a curved plane indicating the transition from one conductivity type to the other conductivity type. Each interface 224, 226 includes a surface section 224a, 226a adjacent to the main surface 202 and a central section 224b, 226b adjacent to the surface section 224a, 226a. In the surface sections 224a, 226a, a horizontal net dopant concentration gradient is smoothed with regard to the adjacent portion of the respective central section 224b, 226b. Along an axis Z, the net dopant concentration gradient has a peak at the transition from the surface section 206a to the extension region 206b. The smooth gradient reduces the electrical field strength between the gate electrode 214 and the respective source/drain region 206, wherein a gate induced drain leakage resulting from the electrical field may be reduced.

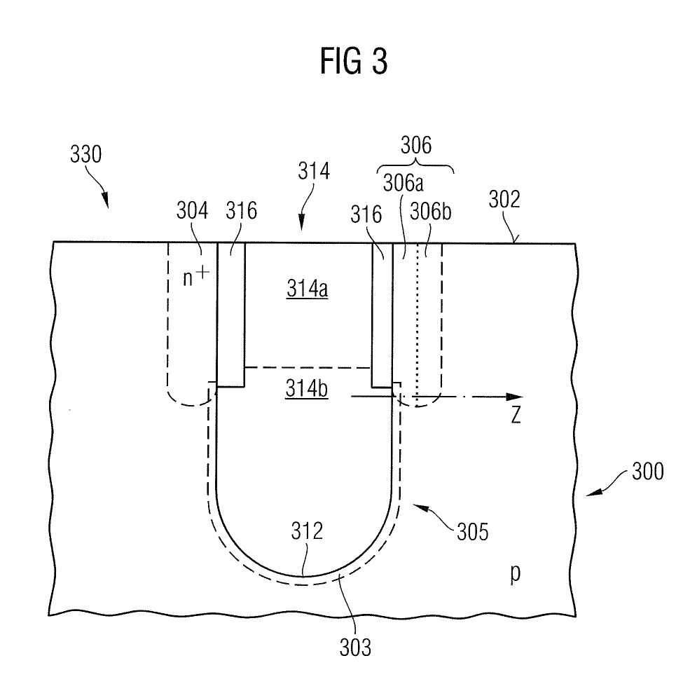

FIG. 3 refers to a 3D-MOSFET 330 or EUD (extended U-groove device). A first and a second source/drain region 304, 306 are formed in a semiconductor substrate 300 adjacent to a main surface 302. The gate electrode 314 is arranged between the first and the second source/drain region 304, 306, wherein a lower edge of the gate electrode 314 may have a greater distance to the main surface 302 than the lower edges of the first and second source/drain regions 304, 306. The lower edges of the first and second source/drain regions 304, 306 may be flush to each other. In accordance with further embodiments, the first and second source/drain regions 304, 306 may extend up to or beyond a lower edge of the gate electrode 314.

According to other embodiments, the distance between the main surface 302 and the lower edge of the first source/drain region 304 is greater or less than the distance between the lower edge of the second source/drain region 306 and the main surface 302. Insulator structures 316 may be formed between an upper portion 314a of the gate electrode 314 and the respective first or second source/drain region 304, 306. The insulator structures 316 may be silicon dioxide or silicon nitride structures or gaps filled with air or vacuum. A gate dielectric 312 separates a lower portion of the gate electrode 314b and the channel region 305. In the on-state of the MOSFET 330, an electric potential applied to the gate electrode 314 controls a current in the adjoining sections of the channel region 305 between a lower edge of the first source/drain region 304 and the lower edge of the second source/drain region 306. In cross-sections before and behind the illustrated cross-section, the gate electrode 314 may wrap around a semiconductor ridge 303 comprising a portion of the channel region 305 as indicated by the dashed line. Portions of the gate electrode 314 on opposing sides of the semiconductor ridge 303 may extend deep into the semiconductor substrate 300, wherein a FinFET-like field effect transistor may be formed. Further, the semiconductor ridge may be thinned to a narrow fin.

The second source/drain region 306 may comprise a surface section 306a adjacent to the insulator structure 316 and the gate dielectric 312 and a central section 306b adjacent to the surface section 306a and opposite to the gate electrode 314. Within the surface section 306a, the net dopant concentration gradient along a cross-section Z perpendicular to the surface of the semiconductor substrate 300, which is perpendicular to the planar main surface 302, increases with increasing distance to the surface and the gate dielectric 312, respectively. In the central region 306b, the net dopant concentration gradient decreases with increasing distance to the surface and the gate dielectric 312, respectively. The first source/drain region 304 may be formed symmetric to the second source/drain region 306 or may comprise one region with decreasing net dopant concentration in a direction of increasing distance to the main surface 302. The gate electrode 314 may comprise a further section above the upper edge of the upper portion 314a. The further section may form part of a connection line running perpendicular to the cross-sectional plane. The further section and spacers arranged along the sidewalls of the further section may form an implant mask during formation of the source/drain regions 304, 306 facilitating the fabrication of source/drain regions with a low doped surface section along the gate dielectric/substrate interface.

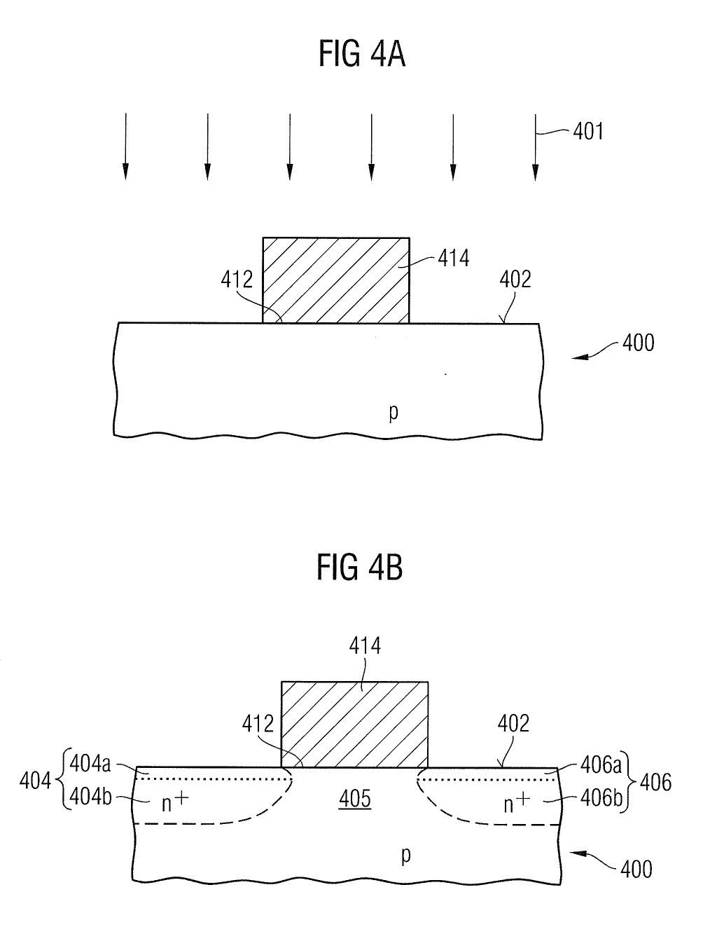

FIGS. 4A-4B refer to a method of forming an n-MOSFET with smooth net dopant concentration gradient in a surface region using segregation or a deep implant of heavy ions. A gate electrode 414 is disposed above a main surface 402 of a substrate 400. Sidewall structures, for example, a sidewall oxide, may extend along the vertical sidewalls of the gate electrode 414. A gate dielectric 412 separates the gate electrode 414 and the substrate 400, which may be p-doped.

As shown in FIG. 4A, an approximately perpendicular implant 401 of heavy ions with low diffusivity may be performed. The ions may have an atomic number of at least 31 (e.g., Sb), or in case of a p-FET (e.g., Ga or In). The gate electrode structure 414 masks the implant 401. The implant 401 is performed with an implantation energy that corresponds to an implant depth of about 5 to 100 nm (e.g., 6 nm).

According to FIG. 4B, the implant forms first and second n-doped source/drain regions 404, 406, which face each other at the gate electrode 414. The net dopant concentration has a peak in a distance to the main surface 402 that is equivalent to the peak implant depth. In surface sections 404a, 406a between the main surface 402 and the first distance, the net dopant concentration increases with increasing distance to the main surface 402. In central regions 404b, 406b beyond the first distance, the net dopant concentration decreases with increasing distance to the main surface 402.

According to another embodiment, the implant 401 may be performed with an implantation dose resulting in a net dopant peak at or close to the main surface 402, wherein a dopant is implanted which is capable of segregating into a structure bearing on the main surface 402, in which the dopant is sufficiently soluble, for example, into the gate dielectric 412, the gate spacers 416 or other structures disposed next to the gate electrode 414 on the main surface 402. A suitable dopant for p-FETs may be, for example, Indium. Both methods described above may be combined with each other.

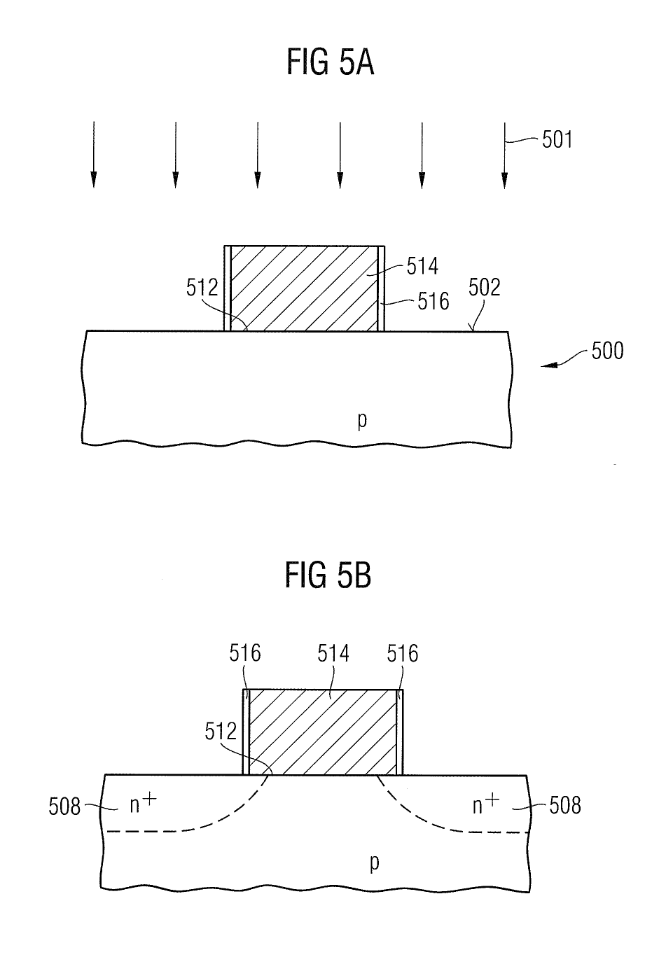

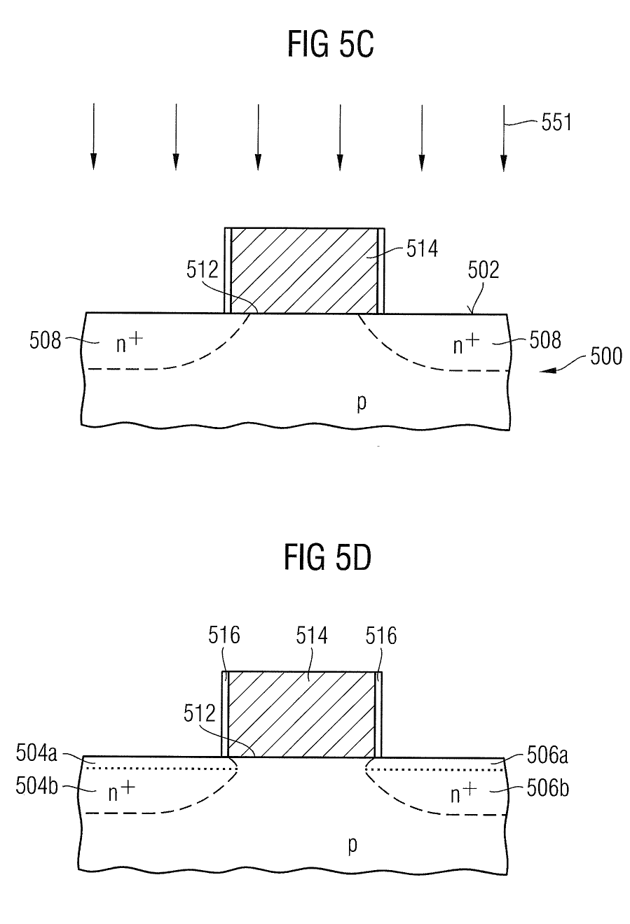

FIGS. 5A to 5D refer to a further method of manufacturing an integrated circuit with n-MOSFETs according to a further embodiment of the invention using a counter implant. According to FIG. 5A, a gate electrode 514 with sidewall spacers 516 is formed on a substrate 500, which may be a p-type substrate. A gate dielectric 512 separates the gate electrode 514 and the semiconductor substrate 500. An implant 501 may be performed, wherein the gate electrode 514 is effective as an implantation mask. The sidewall spacers 516 may be sidewall oxide structures. According to other embodiments the sidewall oxide structures may be formed after the first implant 501 or after the second implant 551.

With regard to FIG. 5B, first and second source/drain regions 508 may result from the implant 501 of FIG. 5A. Due to diffusion processes, the source/drain regions 508 may diffuse below the gate electrode 514. The net dopant concentration decreases with increasing distance to the main surface 502.

According to FIG. 5C, a further implant 551 may be performed, wherein the gate electrode 514 is again effective as an implantation mask. Dopants corresponding to the conductivity type of the channel region 505 may be implanted to be effective as a counter implant in a surface section of the first and second source/drain regions 508.

As shown in FIG. 5D, due to the counter implant 551 of FIG. 5C, a net dopant concentration is reduced in the surface sections 504a, 506a of the first and second source/drain regions 504, 506. In central regions 504b, 506b beyond the first distance, the net dopant concentration along a vertical axis perpendicular to the gate dielectric 512 or the main surface 502 decreases with increasing distance to the main surface 502.

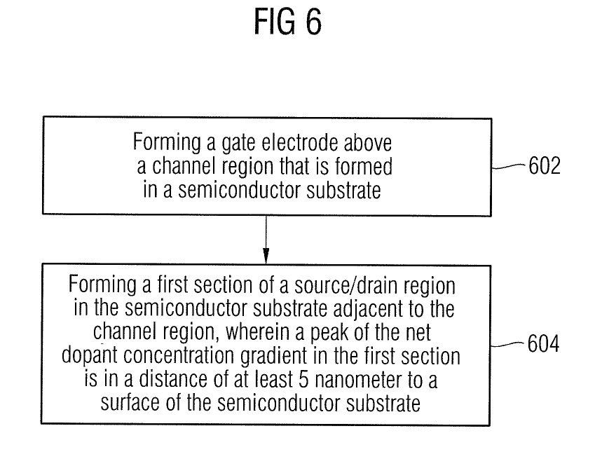

FIG. 6 is a flow-chart referring to a method of forming an integrated circuit comprising a MOSFET. A gate electrode is formed above a channel region in a semiconductor substrate (602). Then, a first section of a source/drain region is formed in the semiconductor substrate adjacent to the channel region, wherein in a surface section of the source/drain region adjacent to a surface of the semiconductor substrate, a net dopant concentration increases with increasing distance to the surface (604).

In other words, a gate electrode of a field effect transistor is formed above a surface of a semiconductor substrate (e.g., a main surface or a sidewall of a vertical or V-shaped groove). Within the semiconductor substrate, a source/drain region of the field effect transistor is formed adjacent to the surface, wherein the net dopant concentration of the source/drain region decreases along a direction perpendicular to the surface towards the gate electrode. The net dopant concentration may decrease towards the gate electrode along a line that is perpendicular to the surface and that intersects the surface at that edge of the gate electrode that is oriented to the source/drain region.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. An integrated circuit comprising:
a field effect transistor including:
a channel region disposed in a semiconductor substrate and adjoining a surface of the semiconductor substrate; and
a source/drain region disposed in the semiconductor substrate and adjoining the surface of the semiconductor substrate, the source/drain region including a first section forming an interface with the channel region, the first section having a first net dopant concentration gradient extending along a direction perpendicular to the surface of the semiconductor substrate, the first net dopant concentration gradient including a peak at a first distance to the surface of at least five nanometers.

2. The integrated circuit of claim 1, wherein the first distance is at least eight nanometers.

3. The integrated circuit of claim 1, wherein the source/drain region further comprises:
a surface section of the substrate adjacent to the surface of the semiconductor substrate; and
a central section of the substrate;
wherein a net dopant concentration gradient extending along a direction parallel to the surface of the semiconductor substrate in the surface section is smoother than in the central section of the substrate at the first distance.

4. The integrated circuit of claim 1, wherein the source/drain region further comprises:
a second section facing the channel region at the first section, the second section having a second net dopant concentration gradient that decreases with increasing distance to the surface of the semiconductor substrate.

5. The integrated circuit of claim 1, further comprising:
a gate dielectric disposed on the surface of the semiconductor substrate and adjoining the channel region; and
a gate electrode disposed on the gate dielectric, the gate dielectric separating the semiconductor substrate and the gate electrode;
wherein a portion of the source/drain region overlaps the gate electrode such that the overlap portion directly faces the gate electrode at the gate dielectric.

6. The integrated circuit of claim 5, wherein the first section comprises the overlap portion.

7. The integrated circuit of claim 5, wherein the first section corresponds to the overlap portion.

8. The integrated circuit of claim 5, wherein the first section is a part of the overlap portion.

9. The integrated circuit of claim 1, wherein the source/drain region further comprises:
an extension region adjacent to the channel region, the extension region forming at least a portion of the first section; and
a deep implantation region extending into the semiconductor substrate to a greater depth than the extension region.

10. The integrated circuit of claim 1, wherein:
the channel region is of a first conductivity type;
the source/drain region is of a second conductivity type that is opposite the first conductivity type; and
the first section comprises a counter doping region including ions of the first conductivity type, the counter doping region reducing a net dopant concentration between the surface and the first distance.

11. The integrated circuit of claim 1, wherein:
the source/drain region is at least partially formed by ions capable of segregating into the gate dielectric or a gate spacer structure disposed on the surface; and
the first section comprises a segregation depletion region formed between the surface and the first distance.

12. The integrated circuit of claim 1, further comprising:
a second source/drain region including a second section forming a further interface with the channel region and comprising a further dopant concentration with a second net dopant concentration gradient extending along a direction perpendicular to the surface, the second net dopant concentration gradient including a peak at a second distance to the surface of at least five nm.

13. An integrated circuit, comprising:
a field effect transistor comprising:
a gate electrode disposed adjacent to a surface of a semiconductor substrate; and
a source/drain region disposed in the semiconductor substrate adjacent to the surface of the semiconductor substrate, the source/drain region comprising a first section with a net dopant concentration that decreases towards the gate electrode along a direction perpendicular to the surface of the semiconductor substrate.

14. The integrated circuit of claim 13, wherein the net dopant concentration of the source/drain region decreases towards the gate electrode along a line that is perpendicular to the surface and that intersects the surface at an edge of the gate electrode that is oriented to the source/drain region.

15. The integrated circuit of claim 13, wherein the net dopant concentration increases with increasing distance to the surface in a portion of the source/drain region disposed between the surface and a first distance to the surface, the first distance being at least five nm.

16. The integrated circuit of claim 15, wherein the net dopant concentration decreases with increasing distance to the surface in a portion of the source/drain region disposed beyond the first distance.

17. The integrated circuit of claim 13, wherein the semiconductor substrate further comprises:
a groove formed in a planar main surface of the semiconductor substrate, the groove including a sidewall that forms the surface adjacent the source/drain region;
wherein the gate electrode is disposed in the groove.

18. The integrated circuit of claim 13, wherein the source/drain region further comprises:
a second section with a second net dopant concentration gradient that decreases with increasing distance to the surface, the second section being spaced apart from the gate electrode by the first section.

19. A method of fabricating an integrated circuit, the method comprising:
forming a gate electrode above a channel region formed in a semiconductor substrate and adjacent to a surface of the semiconductor substrate, the gate electrode being of a first conductivity type; and
forming a first section of a source/drain region in the semiconductor substrate adjacent to the channel region, the first section being of a second conductivity type;
wherein a net dopant concentration of the first section includes a peak disposed at a first distance with respect to the surface, the first distance being at least five nanometers.

20. The method of claim 19, wherein the first distance is at least ten nanometers.

21. The method of claim 19, wherein forming the first section comprises:
implanting dopants with an implant energy equivalent to a peak implant depth with respect to the main surface, wherein the peak implant depth is greater than a diffusion length of the dopants during a following thermal exposure.

22. The method of claim 19, wherein forming the first section comprises:
implanting a dopant with high solubility in silicon oxide.

23. The method of claim 19, wherein forming the first section comprises:
performing a first implant of a dopant of the second conductivity type; and
performing a second implant of a dopant of the first conductivity type to partially neutralize the first implant in a surface section of the source/drain region.

24. A method of fabricating an integrated circuit, the method comprising:
forming a gate electrode above a surface of a semiconductor substrate; and
forming a source/drain region in the semiconductor substrate adjacent to the surface, wherein a net dopant concentration of the source/drain region decreases towards the gate electrode along a direction perpendicular to the surface.

25. The method of claim 24, wherein the source/drain region is formed with a net dopant concentration decreasing towards the gate electrode along a line that is perpendicular to the surface and that intersects the surface at an edge of the gate electrode that is oriented to the source/drain region.
